(19) United States
(12) Patent Application Publication
(10) Pub. No.: US 2023/0205088 A1
(43) Pub. Date: Jun. 29, 2023

(54) NOZZLE FOR SUPPLYING TREATMENT LIQUID AND SUBSTRATE TREATING APPARATUS

(71) Applicant: SEMES CO.,LTD, Cheonan-si (KR)

(72) Inventors: Do Yeon KIM, Yongin-si (KR); Tae Hoon LEE, Osan-si (KR)

(73) Assignee: SEMES CO.,LTD, Cheonan-si (KR)

(21) Appl. No.: 18/146,606

(22) Filed: Dec. 27, 2022

(30) Foreign Application Priority Data
Dec. 27, 2021 (KR) 10-2021-0188973

(51) Int. Cl. G03F 7/16

(52) U.S. Cl. CPC G03F 7/162

(57) ABSTRACT

Provided is an apparatus and a method for liquid-treating a substrate. A substrate treating apparatus may include: a substrate support unit supporting a substrate; and a liquid supply unit applying a photosensitive liquid onto the substrate supported on the substrate support unit, and the liquid supply unit may include an application nozzle supplying the photosensitive liquid, a nozzle arm in which the application nozzle is positioned at one end portion, and a driving member positioned at the other end portion of the nozzle arm and moving the nozzle arm, and the application nozzle may include a nozzle body supported on the nozzle arm, a nozzle tip connected to the nozzle body, and an anti-static surface having an internal flow path through which the photosensitive liquid is ejected and capable of removing static electricity, a nozzle nut member fastened to a thread of the nozzle body so that the nozzle tip is fixed to the nozzle body, and contacting the nozzle tip, and a grounding member having one end contacting the nozzle nut member and the other end grounded through the nozzle arm.

### CROSS-REFERENCE TO RELATED APPLICATIONS

This application claims priority to and the benefit of Korean Patent Application No. 10-2021-0188973 filed in the Korean Intellectual Property Office on Dec. 27, 2021, the entire contents of which are incorporated herein by reference.

### TECHNICAL FIELD

The present invention relates to an apparatus for liquid-treating a substrate.

### BACKGROUND ART

Among semiconductor manufacturing processes for manufacturing semiconductor devices, a photolithography process is a process of forming a desired pattern on a wafer. The photolithography process is generally conducted in a spinner local facility connected to an exposure facility and consecutively treating an application process, an exposure process, and a development process. The spinner local facility sequentially or selectively performs a hexamethyl disilazane (HMDS) process, the application process, a bake process, and the development process.

Here, in the application process as a process of applying a photosensitive liquid onto the surface of the substrate, when static electricity is generated in a nozzle applying the photosensitive liquid, it is easy that the nozzle is contaminated by a polar contaminated substance, so a nozzle cleaning cycle is shortened, and the static electricity is induced to the photosensitive liquid, and as a result, it is easy that particles are directly adsorbed on the substrate.

### SUMMARY OF THE INVENTION

The present invention has been made in an effort to provide an apparatus and a method capable of removing static electricity of a nozzle injecting a treatment liquid.

A problem to be solved by the present invention is not limited to the above-described problem. Other technical problems not mentioned may be apparently appreciated by those skilled in the art from the following description.

According to an aspect of the present invention, a treatment liquid supply nozzle including: a nozzle body; and a nozzle tip connected to the nozzle body, and having an internal flow path through which a treatment liquid is ejected, in which the nozzle tip has an anti-static surface capable of removing static electricity can be provided.

Further, the nozzle tip may be provided by a transparent material so as to check a suck-back, and the anti-static surface may be subjected to ion injection treatment.

Further, the transparent material may include perfluoroalkoxy (PFA).

Further, the nozzle tip may be provided by a transparent material so as to check a suck-back, and the anti-static surface may be surface-treated by ion beams to have a surface resistance value of 10⁶ to 10^{9 Ω.}

Further, the treatment liquid supply nozzle may further include a nozzle nut member fastened to a thread of the nozzle body so that the nozzle tip is fixed to the nozzle body, and contacting the nozzle tip, and the nozzle nut member may have a conductive material and a conductive surface surface-treated with the ion beams.

Further, the treatment liquid supply nozzle may further include a grounding member having one end contacting the nozzle nut member and the other end grounded through a nozzle arm on which the nozzle body is supported.

Further, the grounding member may include a ground line having a ring type terminal connected to each of the nozzle fastening member and the nozzle arm.

Further, the grounding member may include a conductive tape or a conductive pattern connected from the nozzle body up to the nozzle arm.

Further, the anti-static surface may include an outer peripheral surface of the nozzle tip and a partial region of the internal flow path.

According to another aspect of the present invention, a substrate treating apparatus can be provided, which includes: a substrate support unit supporting a substrate; and a liquid supply unit applying a photosensitive liquid onto the substrate supported on the substrate support unit, in which the liquid supply unit includes an application nozzle supplying the photosensitive liquid, a nozzle arm in which the application nozzle is positioned at one end portion, and a driving member positioned at the other end portion of the nozzle arm and moving the nozzle arm, and the application nozzle includes a nozzle body supported on the nozzle arm, and a nozzle tip connected to the nozzle body, and an anti-static surface having an internal flow path through which the photosensitive liquid is ejected and capable of removing static electricity.

Further, the nozzle tip may be provided by a transparent material so as to check a suck-back, and the anti-static surface may be subjected to ion injection treatment.

Further, the transparent material may include perfluoroalkoxy (PFA), and the anti-static surface may have conductivity in which a surface resistance value is 10⁶ to 10^{9 Ω.}

Further, the treatment liquid supply nozzle may further include a nozzle nut member fastened to a thread of the nozzle body so that the nozzle tip is fixed to the nozzle body, and contacting the nozzle tip, and the nozzle nut member may have a conductive material and a conductive surface surface-treated with the ion beams.

Further, the treatment liquid supply nozzle may further include a grounding member having one end contacting the nozzle nut member and the other end grounded through a nozzle arm on which the nozzle body is supported.

Further, the grounding member may include a ground line having a ring type terminal connected to each of the nozzle fastening member and the nozzle arm.

Further, the grounding member may include a conductive tape or a conductive pattern connected from the nozzle body up to the nozzle arm.

Further, the anti-static surface may include an outer peripheral surface of the nozzle tip and a partial region of the internal flow path, and the liquid supply unit may further include a pre-treatment nozzle applying a pre-treatment liquid, a plurality of application nozzles is provided, and the application nozzles and the pre-treatment nozzles may be supported on the nozzle body to be arranged in one direction when viewed from the top.

According to yet another aspect of the present invention, a substrate treating apparatus can be provided, which includes: a substrate support unit supporting a substrate; and a liquid supply unit applying a photosensitive liquid onto the substrate supported on the substrate support unit, in which the liquid supply unit includes an application nozzle supplying the photosensitive liquid, a nozzle arm in which the application nozzle is positioned at one end portion, and a driving member positioned at the other end portion of the nozzle arm and moving the nozzle arm, and the application nozzle includes a nozzle body supported on the nozzle arm, a nozzle tip connected to the nozzle body, and an anti-static surface having an internal flow path through which the photosensitive liquid is ejected and capable of removing static electricity, a nozzle nut member fastened to a thread of the nozzle body so that the nozzle tip is fixed to the nozzle body, and contacting the nozzle tip, and a grounding member having one end contacting the nozzle nut member and the other end grounded through the nozzle arm.

Further, the nozzle tip may be provided by a transparent material so as to check a suck-back, and the anti-static surface may be surface-treated with ion beams, and has conductivity.

Further, the grounding member may include a ground line having a ring type terminal connected to each of the nozzle fastening member and the nozzle arm or a conductive tape or a conductive pattern connected from the nozzle body up to the nozzle arm.

According to an exemplary embodiment of the present invention, a nozzle tip surface made of a synthetic resin is subjected to ion injection treatment to have conductivity, thereby easily removing static electricity generated in a nozzle tip through a grounding member. Therefore, a problem such as contamination of a nozzle tip member, contamination of a processing fluid, etc., can be prevented, which can occur due to existence the static electricity in the nozzle tip.

The effect of the present invention is not limited to the foregoing effects. Non-mentioned effects will be clearly understood by those skilled in the art from the present specification and the accompanying drawings.

### BRIEF DESCRIPTION OF THE DRAWINGS

FIG. 1 is a plan view of a substrate treatment facility according to an exemplary embodiment of the present invention.

FIG. 2 is a cross-sectional view of the facility of FIG. 1 taken along line A-A.

FIG. 3 is a cross-sectional view of the facility of FIG. 1 taken along line B-B.

FIG. 4 is a cross-sectional view of the facility of FIG. 1 taken along line C-C.

FIG. 5 is a plan view illustrating a substrate treating apparatus of FIG. 1.

FIG. 6 is a cross-sectional view illustrating the substrate treating apparatus of FIG. 1.

FIG. 7 is an enlarged diagram of a nozzle member of FIG. 6.

FIG. 8 is a side view illustrating the nozzle member illustrated in FIG. 7.

FIG. 9 is a cross-sectional view for describing an application nozzle illustrated in FIG. 7.

FIG. 10 is an exploded perspective view of the application nozzle illustrated in FIG. 9.

FIG. 11 is a cross-sectional perspective view of a nozzle tip.

FIG. 12 is a diagram illustrating another example of a grounding member.

### DETAILED DESCRIPTION

Hereinafter, an exemplary embodiment of the present invention will be described in more detail with reference to the accompanying drawings. The exemplary embodiment of the present invention can be modified in various forms, and it should not be construed that the scope of the present invention is limited to exemplary embodiments described below. The exemplary embodiments are provided to more completely describe the present invention to those skilled in the art. Therefore, a shape of an element in the drawing is exaggerated in order to emphasizing a more definite description.

A facility of the exemplary embodiment may be used for performing a photolithography process for a substrate such as a semiconductor wafer or a flat panel display panel. In particular, the facility of the exemplary embodiment may be connected to an exposure apparatus, and used for performing an application process and a development process for a substrate. Hereinafter, a case where a wafer is used as the substrate will be described as an example.

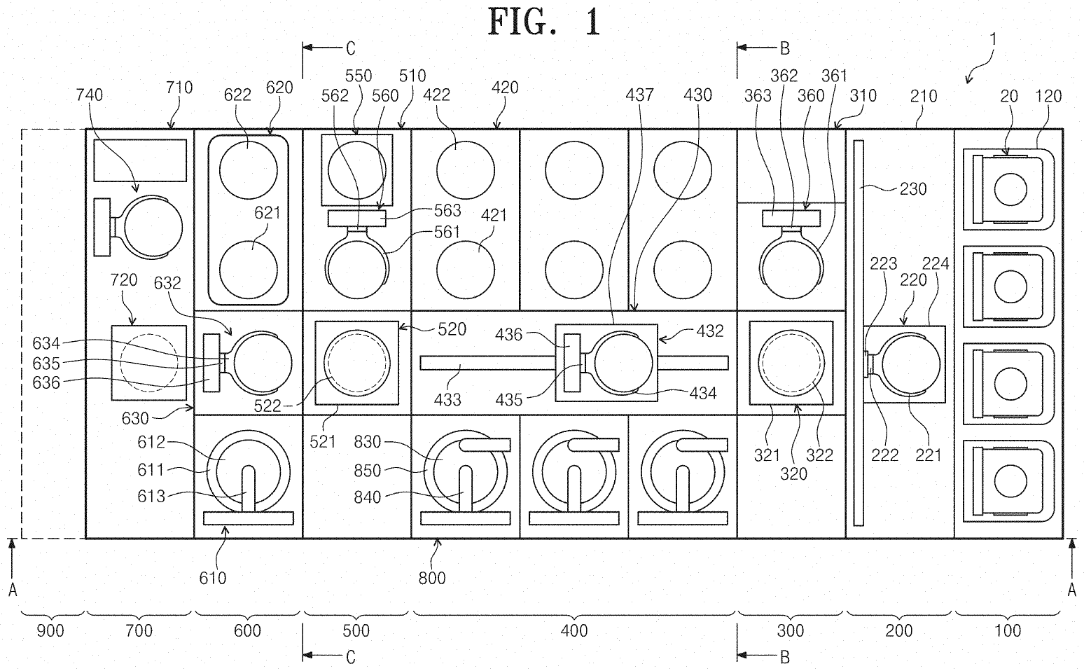

Hereinafter, a substrate treatment facility of the present invention will be described with reference to FIGS. 1 to 12.

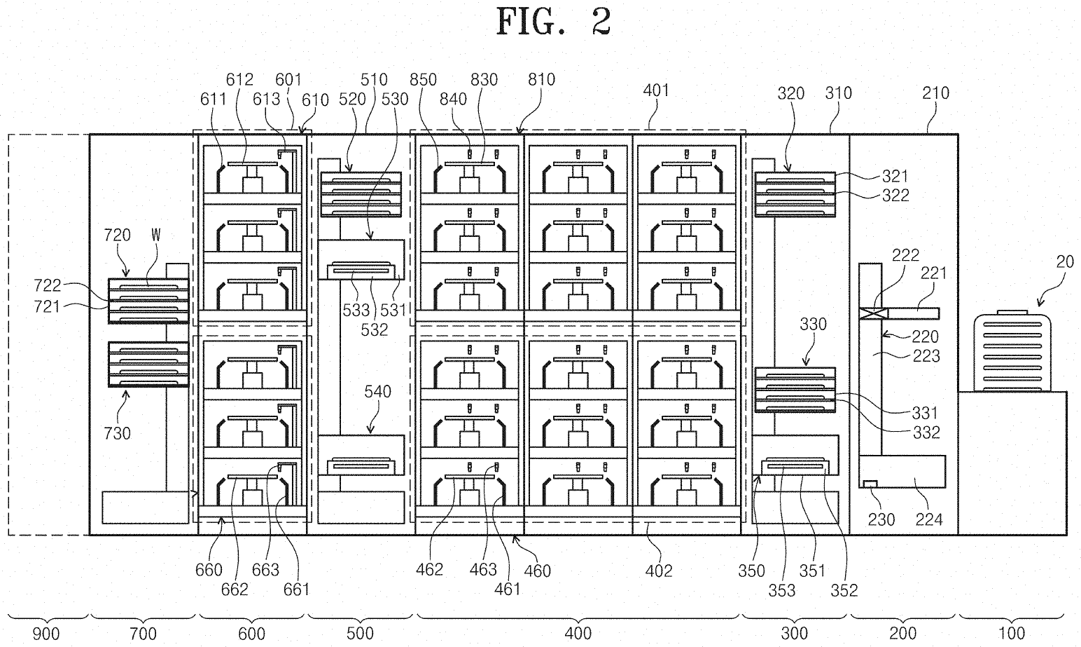

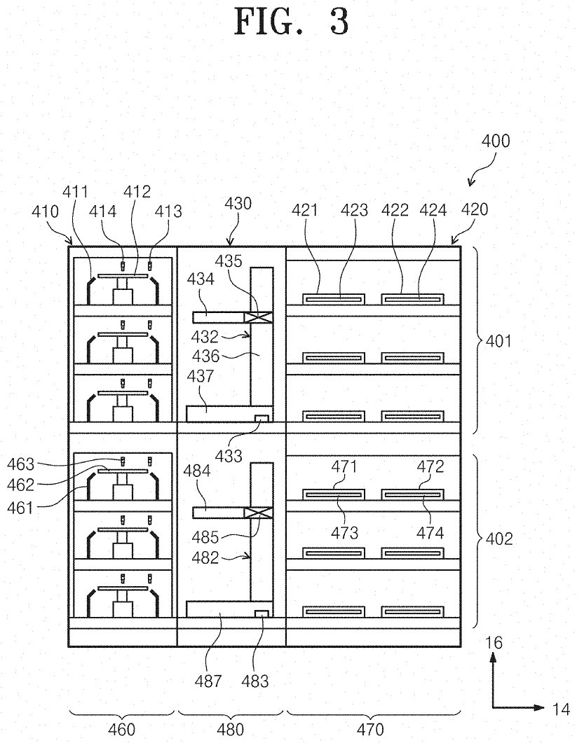

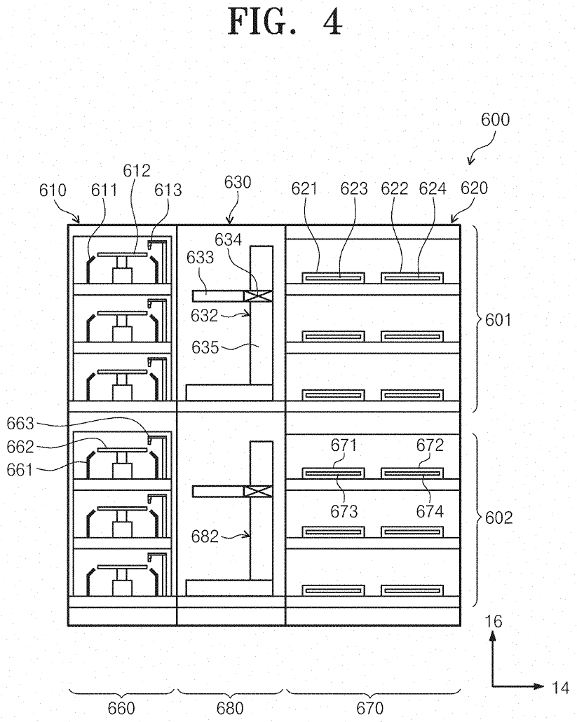

FIG. 1 is a plan view of a substrate treatment facility according to an exemplary embodiment of the present invention, FIG. 2 is a cross-sectional view of the facility of FIG. 1 taken along line A-A, FIG. 3 is a cross-sectional view of the facility of FIG. 1 taken along line B-B, and FIG. 4 is a cross-sectional view of the facility of FIG. 1 taken along line C-C.

Referring to FIGS. 1 to 4, the substrate treatment facility 1 includes a load port 100, an index module 200, a first buffer module 300, an application and development module 400, a second buffer module 500, an exposure pre-post treatment module 600, and an interface module 700. The load port 100, the index module 200, the first buffer module 300, the application and development module 400, the second buffer module 500, the exposure pre-post treatment module 600, and the interface module 700 are sequentially arranged in line in one direction.

Hereinafter, a direction in which load port 100, the index module 200, the first buffer module 300, the application and development module 400, the second buffer module 500, the exposure pre-post treatment module 600, and the interface module 700 are arranged will be referred to as a first direction 12, a direction vertical to the first direction 12 when viewed from the top will be referred to as a second direction 14, and a direction vertical to each of the first direction 12 and the second direction 14 will be referred to as a third direction 16.

A substrate W is moved while being stored in a cassette 20. In this case, the cassette 20 has a structure which may be sealed from the outside. For example, a front open unified pod (FOUP) having a door at a front may be used as the cassette 20.

Hereinafter, the load port 100, the index module 200, the first buffer module 300, the application and development module 400, the second buffer module 500, the exposure pre-post treatment module 600, and the interface module 700 will be described in detail.

The load port 100 has a mounting table 120 on which the cassette 20 storing the substrates W is placed. A plurality of mounting tables 120 is provided, and the mounting tables 200 are arranged in line in the second direction 14. In FIG. 1, four mounting tables 120 are provided.

The index module 200 transfers the substrate W between the cassette 20 placed on the mounting table 120 and the first buffer module 300. The index module 200 has a frame 210, an index robot 220, and a guide rail 230. The frame 210 is generally provided in a rectangular parallelepiped shape in which an inside is empty, and is placed between the load port 100 and the first buffer module 300. The frame 210 of the index module 200 may be provided at a height lower than the frame 310 of the first buffer module 300 to be described below. The index robot 220 and the guide rail 230 are placed in the frame 210. The index robot 220 has a structure in which 4-axis driving is possible so that a hand 221 directly handling the substrate W is movable and rotatable in the first direction 12, the second direction 14, and the third direction 16. The index robot 220 has a hand 221, an arm 222, a support 223, and a bracket 224. The hand 221 is fixedly installed in the arm 222. The arm 222 is provided in a stretchable structure and a rotatable structure. The support 223 is placed in the third direction 16 which is a longitudinal direction thereof. The arm 222 is coupled to the support 223 to be movable along the support 223. The support 223 is fixedly coupled to the bracket 224. The guide rail 230 is provided to be placed in the second direction 14 which is the longitudinal direction thereof. The bracket 224 is coupled to the guide rail 230 to be linearly movable along the guide rail 230. Further, although not illustrated, a door opener opening/closing a door of the cassette 20 is further provided to the frame 210.

The first buffer module 300 includes a frame 310, a first buffer 320, a second buffer 330, a cooling chamber 350, and a first buffer robot 360. The frame 310 is generally provided in the rectangular parallelepiped shape in which the inside is empty, and is placed between the index module 300 and the application and development module 400. The first buffer 320, the second buffer 330, the cooling chamber 350, and the first buffer robot 360 are positioned in the frame 310. The cooling chamber 350, the second buffer 330, and the first buffer 320 are arranged in the third direction 16 from the bottom in sequence. The first buffer 320 is positioned at a height corresponding to an application module 401 of the application and development module 400 to be described below, and the second buffer 330 and the cooling chamber 350 are positioned at a height corresponding to a development module 402 of the application and development module 400 to be described below. The first buffer robot 360 is positioned to be spaced apart from the second buffer 330, the cooling chamber 350, and the first buffer 320 by a predetermined distance in the second direction 14.

Each of the first buffer 320 and the second buffer 330 temporarily keeps a plurality of substrates W. The second buffer 330 includes a housing 331 and a plurality of supports 332. The supports 332 are placed in the housing 331, and provided to be spaced apart from each other in the third direction 16. One substrate W is placed on each support 332. The housing 331 has an opening (not illustrated) in a direction in which the index robot 220 is provided, a direction in which the first buffer robot 360 is provided, and a direction in which a development unit robot 482 is provided so that the index robot 22, the first buffer robot 360, and the development unit robot 482 of the development module 402 to be described below may load or unload the substrate W on or from the support 332 in the housing 331. The first buffer 320 has a substantially similar structure to the second buffer 330. However, the housing 321 of the first buffer 320 has the opening in the direction in which the first buffer robot 360 is provided and a direction in which an application unit robot 432 positioned in the application module 401 to be described below is provided. The number of supports 322 provided in the first buffer 320 and the number of supports 332 provided in the second buffer 330 may be the same as or different from each other. According to an example, the number of supports 332 provided in the second buffer 330 may be larger than the number of supports 322 provided in the first buffer 320.

The first buffer robot 360 transfers the substrate W between the first buffer 320 and the second buffer 330. The first buffer robot 360 has a hand 361, an arm 362, and a support 363. The hand 361 is fixedly installed in the arm 362. The arm 362 is provided in the stretchable structure to allow the hand 361 to be movable in the second direction 14. The arm 362 is coupled to the support 363 to be linearly movable along the support 363 in the third direction 16. The support 363 has an extension length from a location corresponding to the second buffer 330 to a location corresponding to the first buffer 320. The support 363 may be provided to be longer than the extension length upward or downward. The first buffer robot 360 may be just provided so that the hand 361 is 2-axially driven in the second direction 14 and the third direction 16.

The cooling chamber 350 cools each substrate W. The cooling chamber 350 includes a housing 351 and a cooling plate 352. The cooling plate 352 has a cooling means 353 that cools an upper surface on which the substrate W is placed and the substrate W. As the cooling means 353, various schemes such as cooling by cooling water or cooling using a thermoelectric element may be used. Further, a lift pin assembly (not illustrated) that locates the substrate W on the cooling plate 352 may be provided in the cooling chamber 350. The housing 351 has an opening (not illustrated) in the direction in which the index robot 220 is provided and the direction in which the development unit robot 482 is provided so that the index robot 220, and the development unit robot 482 provided in the development module 402 to be described below may load or unload the substrate W on or from the cooling plate 352. Further, doors (not illustrated) that open/close the opening may be provided in the cooling chamber 350.

The application and development module 400 performs a process of applying a photoresist onto the substrate W after the exposure process and a process of developing the substrate W after the exposure process. The application and development module 400 has the substantially rectangular parallelepiped shape. The application and development module 400 includes the application module 401 and the development module 402. The application module 401 and the development module 402 are placed to be partitioned from each other by a layer. According to an example, the application module 401 is positioned above the development module 402.

The application module 401 includes a process of applying a photosensitive liquid such as the photoresist to the substrate W and a heat treatment process such as heating and cooling for the substrate W before and after the resist application process. The application module 401 includes a resist application chamber 410, a bake chamber 420, and a transfer chamber 430. The resist application chamber 410, the bake chamber 420, and the transfer chamber 430 may be sequentially arranged in the second direction 14. Therefore, the resist application chamber 410 and the bake chamber 420 are positioned to be spaced apart from each other with the transfer chamber 430 interposed therebetween in the second direction 14. A plurality of resist application chambers 410 is provided, and provided in each of the first direction 12 and the second direction 16. In the drawing, an example in which six resist application chambers 410 are provided is illustrated. A plurality of bake chambers 420 is provided in each of the first direction 12 and the third direction 16. In the drawing, an example in which six bake chambers 420 are provided is illustrated. However, unlike this, more bake chambers 420 may be provided.

The transfer chamber 420 is positioned in line with the first buffer 320 of the first buffer module 300 in the first direction 12. An application unit robot 432 and a guide rail 433 are positioned in the transfer chamber 430. The transfer chamber 430 has a substantially rectangular shape. The application unit robot 432 transfers the substrate W between bake chambers 420, resist application chambers 400, the first buffer 320 of the first buffer module 300, and the a first cooling chamber 520 of the second buffer module 500 to be described below. The guide rail 433 is placed so that the longitudinal direction is in line with the first direction 12. The guide rail 433 guides the application unit robot 432 to linearly move in the first direction 12. The application unit robot 432 has a hand 434, an arm 435, a support 436, and a bracket 437. The hand 434 is fixedly installed in the arm 435. The arm 435 is provided in the stretchable structure to allow the hand 434 to be movable in the horizontal direction. The support 436 is provided to be placed in the third direction 16 which is the longitudinal direction thereof. The arm 435 is coupled to the support 436 to be linearly movable along the support 436 in the third direction 16. The support 436 is fixedly coupled to the bracket 437, and the bracket 437 is coupled to the guide rail 433 to be linearly movable along the guide rail 433.

All of the resist application chambers 410 have the same structure. However, the types of photoresists used in the respective resist application chambers 410 may be different from each other. As an example, as the photoresist, a chemical amplification resist may be used. The resist application chamber 410 is provided to a substrate treating apparatus that applies the photoresist onto the substrate W. The substrate treating apparatus 800 performs a liquid application process.

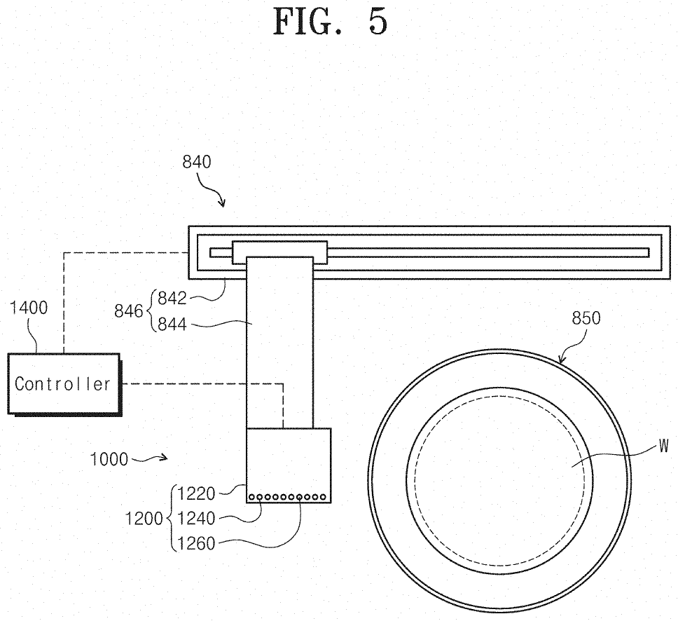

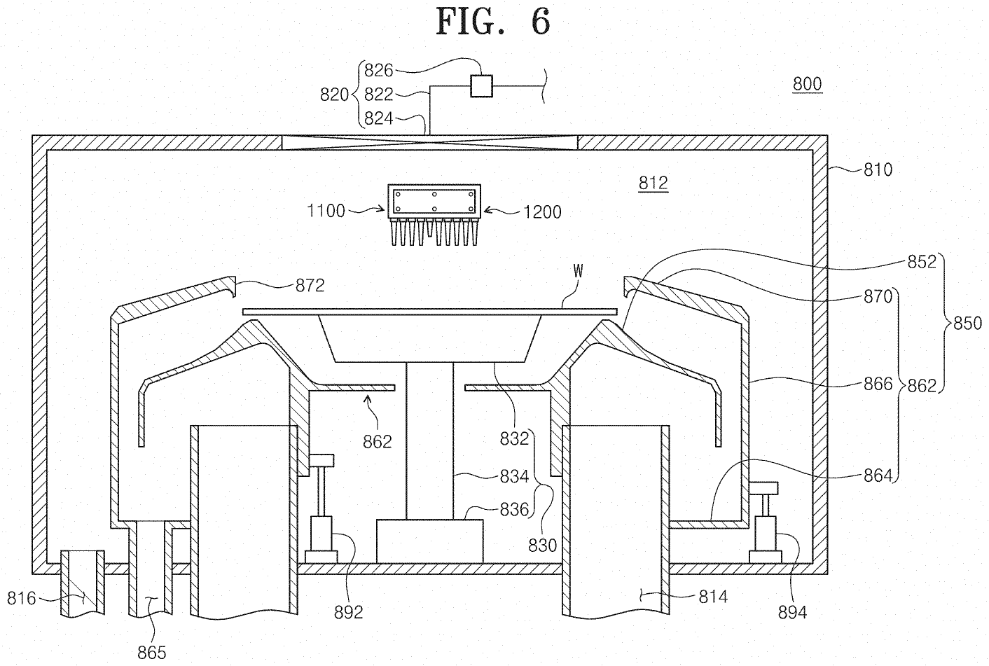

FIG. 5 is a plan view illustrating a substrate treating apparatus of FIG. 1 and FIG. 6 is a cross-sectional view illustrating the substrate treating apparatus of FIG. 1.

Referring to FIGS. 5 and 6, the substrate treating apparatus 800 includes a housing 810, an air current providing unit 820, a substrate support unit 830, a treatment container 850, an elevation unit 890, a liquid supply unit 840, and a controller 880.

The housing 810 is provided in a rectangular cylindrical shape having a treatment space 812 therein. An opening (not illustrated) is formed at one side of the housing 810. The opening serves as an inlet through which the substrate W is loaded and unloaded. A door (not illustrated) is installed in the opening, and the door opens/closes the opening. The door occludes the opening to seal the treatment space 812 of the housing 810 when the substrate treatment process is conducted. An inner exhaust port 814 and an outer exhaust port 816 are formed on a lower surface of the housing 810. An air current formed inside the housing 810 is exhausted to the outside through the inner exhaust port 814 and the outer exhaust port 816. According to an example, the air current introduced into the treatment container 850 may be exhausted through the inner exhaust port 814 and the air current provided to the outside of the treatment container 850 may be exhausted through the outer exhaust port 816.

The air current providing unit 820 forms a descending air current in the treatment space 812 of the housing 810. The air current providing unit 820 includes an air current supply line 822, a fan 824, and a filter 826. The air current supply line 822 is connected to the housing 810. The air current supply line 822 supplies external clean air to the housing 810. The filter 826 filters the clean air provided from the air current supply line 822. The filter 826 removes impurities included in the air. The fan 824 is installed on the upper surface of the housing 810. The fan 824 is positioned at a central area of the upper surface of the housing 810. The fan 824 forms the descending air current in the treatment space 812 of the housing 810. When the clean air is supplied to the fan 824 from the air current supply line 822, the fan 824 supplies the clean air downward. According to an example, the fan 824 may supply air currents having different flow rates to the treatment space according to the substrate treatment step.

The substrate support unit 830 supports the substrate W in the treating space 812 of the housing 810. The substrate support unit 830 rotates the substrate W. The substrate support unit 830 includes a spin chuck 832, a rotation axis 834, and a driver 836. The spin chuck 832 is provided to a substrate support member 832 supporting the substrate. The spin chuck 832 is provided to have a circular plate shape. The substrate W is in contact with a top surface of the spin chuck 832. The spin chuck 832 is provided to have a smaller diameter than the substrate W. According to an example, the spin chuck 832 vacuum-suctions the substrate W to chuck the substrate W. Optionally, the spin chuck 832 may be provided to an electrostatic chuck that chucks the substrate W by using static electricity. Further, the spin chuck 832 may chuck the substrate W with physical force.

The rotation axis 834 and the driver 836 are provided to rotation driving members 834 and 836 that rotate the spin chuck 832. The rotation axis 834 supports the spin chuck 832 below the spin chuck 832. The rotation axis 834 is provided toward the vertical direction which is the longitudinal direction thereof. The rotation axis 834 is provided to be rotatable around the central axis. The driver 836 provides driving force so as to rotate the rotation axis 834. For example, the driver 836 may be a motor of which a rotational speed of the rotation axis is variable. The rotation driving members 834 and 836 may rotate the spin chuck 832 at different rotational speeds according to the substrate treatment step.

The treatment container 850 is positioned in the treatment space 812 of the housing 810. The treatment container 850 is provided to cover the substrate support unit 830. The treatment container 850 may have a cup shape of which an upper portion is opened. The treatment container 850 has an inner cup 852 and an outer cup 862.

The inner cup 852 is provided in a circular cup shape of covering the rotation axis 834. When viewed from the top, the inner cup 852 is positioned to overlap with the inner exhaust port 814. When viewed from the top, a top surface of the inner cup 852 is provided so that an outer region and an inner region of the top surface are inclined at different angles. According to an example, the outer region of the inner cup 852 is provided to face a downward inclined direction as being far from the substrate support unit 830, and the inner region is provided to face an upward inclined direction as being far from the substrate support unit 830. A point where the outer region and the inner region of the inner cup 852 meet each other is provided to correspond to a side end portion of the substrate W in the vertical direction. A top outer region of the inner cup 852 is provided to be rounded. The top outer region of the inner cup 852 is provided to be concave downward. The top outer region of the inner cup 852 is provided as a region in which the treatment liquid flows.

The outer cup 862 is provided in a cup shape of covering the substrate support unit 830 and the inner cup 852. The outer cup 862 has a bottom wall 864, a side wall 866, a top wall 870, and an inclination wall 870. The bottom wall 864 is provided to have a circular plate shape having a hollow. A recover line 865 is formed on the bottom wall 864. The recovery line 865 may recover the treatment liquid supplied onto the substrate W. The treatment liquid recovered by the recovery line 865 may be reused by an external liquid reproduction system. The side wall 866 is provided to have the circular cylindrical shape of covering the substrate support unit 830. The side wall 866 extends in the vertical direction from the side end portion of the bottom wall 864. The side wall 866 extends upward from the bottom wall 864.

The inclination wall 870 extends in an inner direction of the outer cup 862 from the upper end of the side wall 866. The inclination wall 870 is provided to be close to the substrate support unit 830 upward. The inclination wall 870 is provided to have a ring shape. The upper end of the inclination wall 870 is positioned to be higher than the substrate W supported on the substrate support unit 830.

The elevation unit 890 elevates each of the inner cup 852 and the outer cup 862. The elevation unit 890 includes an inner movement member 892 and an outer movement member 894. The inner movement member 892 elevates the inner cup 852 and the outer movement member 894 elevates the outer cup 862.

The liquid supply unit 840 supplies the photosensitive liquid and a pre-treatment liquid onto the substrate W. The liquid supply unit 840 includes a movement member 846 and a nozzle member 1000.

The movement member 846 moves the nozzle member 1000 to the process location or the waiting location. Here, the process location is a location at which the nozzle member 1000 faces the substrate W supported on the substrate support unit 830, and the waiting location is a location at which the nozzle member 1000 deviates from the process location. For example, the nozzle member 1000 and the substrate W may be positioned at the process location to be opposite to each other in the vertical direction.

The movement member 846 moves the nozzle member 1000 in one direction. According to an example, the movement member 846 linearly moves the nozzle member 1000 in one direction. One direction may be a direction parallel to the first direction 12. The movement member 846 includes a guide rail 842 and an arm 844. The guide rail 842 is provided so that the longitudinal direction faces the horizontal direction. The guide rail 842 may have a longitudinal direction that faces the first direction 12. The guide rail 842 is positioned at one side of the treatment container 850. The arm 844 is installed in the guide rail 842. The arm 844 is moved by a driving member (not illustrated) provided in the guide rail 842. For example, the driving member may be a linear motor. When viewed from the top, the arm 844 is provided a bar shape having a longitudinal direction vertical to the guide rail 842. The nozzle member 1000 is installed on a bottom of an end of the arm 844. The nozzle member 1000 moves jointly with the arm 844.

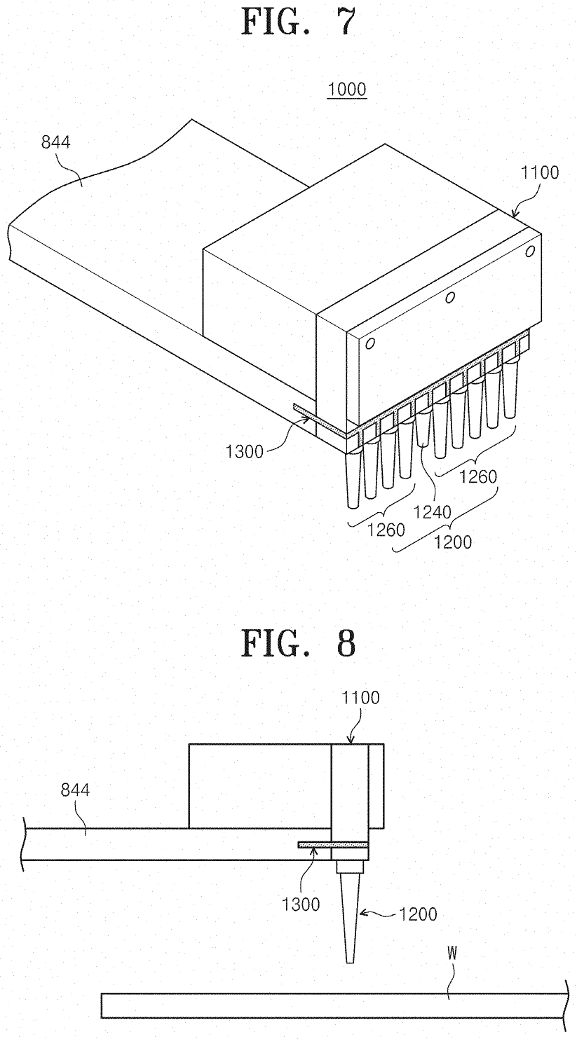

FIG. 7 is an enlarged diagram of a nozzle member of FIG. 6 and FIG. 8 is a side view illustrating the nozzle member illustrated in FIG. 7.

Referring to FIGS. 7 and 8, the nozzle member 1000 may include an ejection member 1200 having a plurality of nozzles ejecting the photosensitive liquid and the pre-treatment liquid by a dropping scheme, a nozzle body 1100 supporting the ejection member 1200, and a grounding member 1300. The nozzles may include a pre-treatment nozzle 1240 and an application nozzle 1260, and the nozzles may be provided in the same configuration. The nozzle body 1100 may be supported on a nozzle arm 844. The nozzle body 1100 may be a synthetic resin material, and the nozzle arm 844 may be a metallic material such as aluminum having a conductive property.

Each nozzle is provided so that an ejection hole faces a vertical downward direction. When viewed from the top, the pre-treatment nozzle 1240, and the application nozzle 1260 are arranged in a direction parallel to a movement direction of the nozzle member 1000. According to an example, the pre-treatment nozzle 1240, and the application nozzle 1260 may be arranged in line in one direction which is the movement direction. A plurality of application nozzles 1260 may be provided in one direction. The pre-treatment nozzle 1240 may be arranged between the plurality of application nozzles 1260. The pre-treatment nozzle 1240 may eject the pre-treatment liquid by the dropping scheme. The pre-treatment liquid may be provided as a liquid including a property close to the photosensitive liquid between a hydrophile property and a hydrophobic property. When the photosensitive liquid has the hydrophobic property, the pre-treatment liquid may be provided as a thinner. The pre-treatment liquid may increase an adhesive force between the substrate W and the photosensitive liquid.

The plurality of application nozzles 1260 may eject the photosensitive liquid. The respective application nozzles 1260 eject a photosensitive liquid of the same flow rate. According to an example, a plurality of application nozzles 1260 may be provided at one side of the pre-treatment nozzle 1240 based on the pre-treatment nozzle 1240, and a plurality of application nozzles 1260 may be provided at the other side opposite thereto. The same number of application nozzles 1260 may be arranged at both sides of the pre-treatment nozzle 1240, respectively to be symmetric. The respective application nozzles 1260 may eject different types of photosensitive liquids. For example, one application nozzle 1260 of the plurality of application nozzles 1260 may eject the photosensitive liquid during a process of treating a single substrate W. An ejection end of the pre-treatment nozzle 1240 is positioned to be higher than the application nozzles 1260. This is to prevent the photosensitive liquid from being scattered and attached to the pre-treatment nozzle 1240 while being ejected.

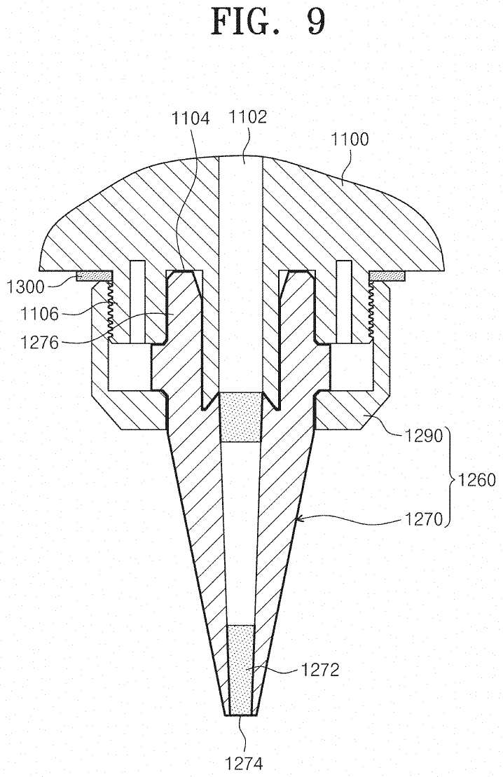

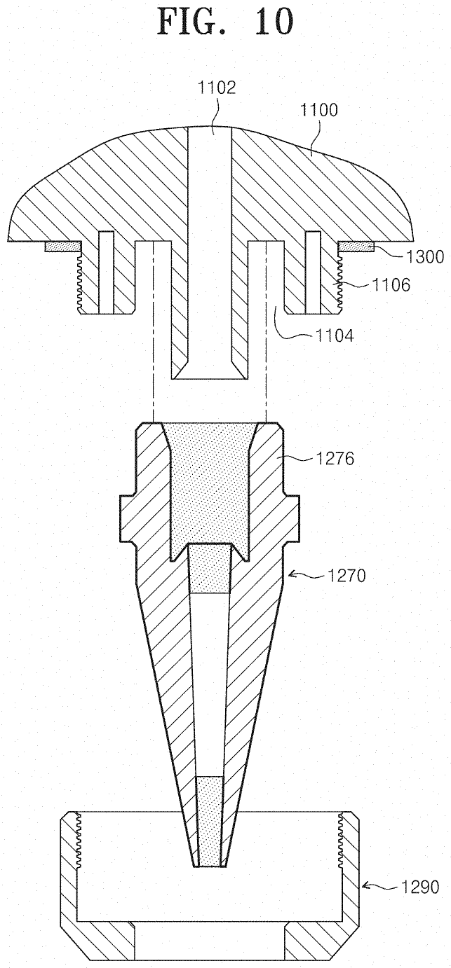

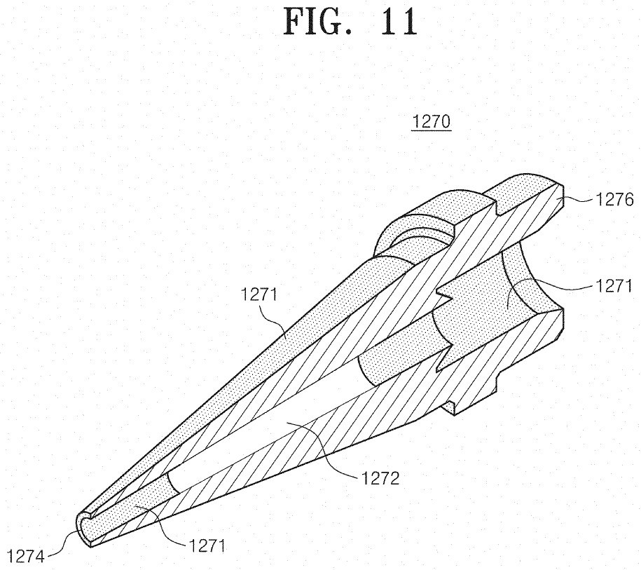

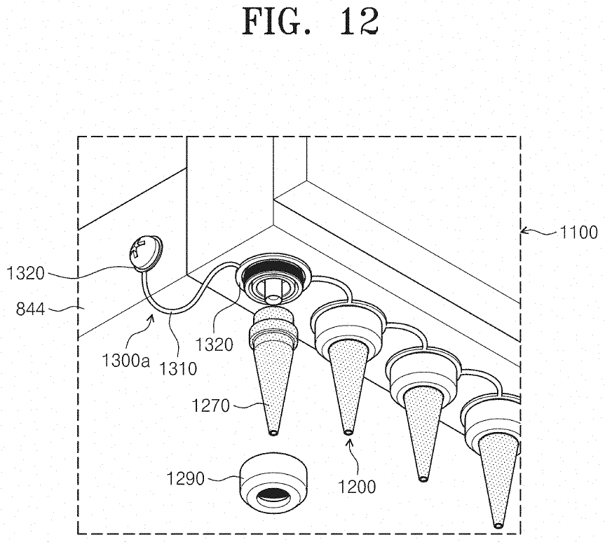

FIG. 9 is a cross-sectional view for describing an application nozzle illustrated in FIG. 7, FIG. 10 is an exploded perspective view of the application nozzle illustrated in FIG. 9, and FIG. 11 is a cross-sectional perspective view of a nozzle tip.

Referring to FIGS. 9 to 11, an application nozzle 1260 may include a nozzle tip 1270 and a nozzle nut member 1290.

The nozzle body 1100 may include a first flow path 1102 which is connected to a photosensitive liquid supply source and through which a treatment fluid passes. The bottom of the nozzle body 1100 may include a connection unit 1104 to which the nozzle tip 1270 is connected and a fastening unit 1106 to which the nozzle nut member 1290 is fastened.

The nozzle tip 1270 includes a first flow path 1272 which is in communication with the first flow path 1102 of the nozzle body, and an ejection hole 1274 which is in communication with the second flow path 1272 and exposed to the outside. The nozzle tip 1270 has a connection end 1276 connected to the connection unit 1104 of the nozzle body. For example, the connection end 1276 may be formed to be fitted into the connection unit 1104. To this end, the connection unit 1104 may be formed in the form of a groove having a predetermined depth, and the connection end 1276 may be formed in the form of a protrusion having a predetermined length. However, the present invention is not limited to such a configuration. The connection end 1276 of the nozzle tip 1270 is fitted into the connection unit 1104, and as a result, the flow path 1102 and the second flow path 1272 may be in communication with each other.

The nozzle nut member 1290 is fastened to the fastening unit 1106 of the nozzle body. The nozzle nut member 1290 may be formed in the form of a nut. A female thread 1292 is formed on the inner surface of the nozzle nut member 1290, and the female thread is formed in the fastening unit 1106 to be screw-connected to each other. As another example, a fastening member may be fastened to the fastening unit through various schemes including press-fit, clamp, latch, etc. The nozzle nut member 1290 may have a through hole 1290 through which the nozzle tip 1270 passes. As a result, a part of the nozzle tip 1270 passes through the through hole 1299 of the fastening member 1290, and as a result, the ejection hole 1274 of the nozzle tip may be exposed to the outside. Since the ejection hole 1274 of the nozzle tip may be exposed to the outside, characteristics of the treatment fluid such as an ejection form of the treatment fluid ejected from the ejection hole 1270 of the nozzle tip 1270, whether the ejection of the treatment fluid is stopped, etc., may be easily measured. Meanwhile, the nozzle nut member 1290 may have a conductive material or a conductive surface surface-treated with an ion beam.

Meanwhile, the nozzle tip 1270 has an anti-static surface 1271 capable of removing the static electricity. As illustrated in FIG. 11, the anti-static surface 1271 (a surface hatching-treated with dots) may include an outer peripheral surface of the nozzle tip 1270, and a part of the second flow path. The nozzle tip 1272 may be provided as a transparent material so as to check a suck-back. The transparent material may include perfluoroalkoxy (PFA). Even though the nozzle tip 1270 of the transparent perfluoroalkoxy (PFA) material is subjected to plasma ion treatment, the nozzle tip 1270 is translucent, so the inside of the nozzle may be checked by a vision camera. The anti-static surface 1271 may be surface-treated by a plasma ion injection method. As an example, the anti-static surface preferably has a conductivity in which a surface resistance value is 10⁶ to 10⁹ Ω. One end of the grounding member 1300 may be provided onto one surface adjacent to the fastening unit 1106 to be in contact with the nozzle nut member 1290. The other end of the grounding member 1300 is connected to a nozzle arm 844 supporting a nozzle body 1100. The grounding member 1300 may be provided in the form of a conductive line (a conductive tape or a conductive pattern) connected from the nozzle body 1100 to the nozzle arm 844.

In the application nozzle 1260 having such a structure, the static electricity generated in the process of ejecting the photosensitive liquid may be removed through the nozzle tip, the nozzle nut member, and the grounding member. Therefore, the existing form and material of the application nozzle are not changed, and a conductive surface is formed through ion injection into the surface, and a grounding path can be formed.

FIG. 12 is a diagram illustrating another example of a grounding member.

As illustrated in FIG. 12, a grounding member 1300a may include a ground line 1310 having a ring type terminal 1320 connected to each of the nozzle number member 1290 and the nozzle arm 844. The ring type terminals connected to the nozzle nut members, respectively may be connected to each other by the grounding line.

Meanwhile, although not illustrated, the grounding member may remove the static electricity of the nozzle tip by a scheme of allowing a bolt to penetrate the nozzle nut member to be in contact with the outer peripheral surface of the nozzle tip, and connecting the grounding line to the bolt. Referring back to FIGS. 1 to 4, the bake chamber 420 heat-treats the substrate W. For example, the bake chambers 420 performs a pre-bake process of removing an inorganic substance or moisture from the surface of the substrate W by heating the substrate W at a predetermined temperature before applying the photoresist or a soft bake process performed after applying the photoresist onto the substrate W, and performs a cooling process of cooling the substrate W after each heating process. The bake chamber 420 has a cooling plate 421 or a heating plate 422. A cooling means 423 such as cooling water or a thermoelectric element is provided in the cooling plate 421. Further, a cooling means 422 such as a heat wire or the thermoelectric element is provided in the heating plate 424. Each of the cooling plate 421 and the heating plate 422 may be provided in one bake chamber 420. Optionally, some of the bake chambers 420 may include only the cooling plate 421, and the other some may include only the heating plate 422.

The development module 402 includes a development process of removing a part of the photoresist by supplying a development liquid onto the substrate W in order to obtain a pattern, and a heat-treatment process such as heating and cooling performed with respect to the substrate W before and after the development process. The development module 402 includes a development chamber 460, a bake chamber 470, and a transfer chamber 480. The development chamber 460, the bake chamber 470, and the transfer chamber 480 may be sequentially arranged in the second direction 14. Therefore, the development chamber 460 and the bake chamber 470 are positioned to be spaced apart from each other with the transfer chamber 480 interposed therebetween in the second direction 14. A plurality of development chambers 460 is provided, and provided in each of the first direction 12 and the second direction 16. In the drawing, an example in which six development chambers 460 are provided is illustrated. A plurality of bake chambers 470 is provided in each of the first direction 12 and the third direction 16. In the drawing, an example in which six bake chambers 470 are provided is illustrated. However, unlike this, more bake chambers 470 may be provided.

The transfer chamber 480 is positioned in line with the second buffer 330 of the first buffer module 300 in the first direction 12. A development unit robot 482 and a guide rail 483 are positioned in the transfer chamber 480. The transfer chamber 480 has a substantially rectangular shape. The development unit robot 482 transfers the substrate W between development chambers 460, the second buffer 330 and the cooling chamber 350 of the first buffer module 300, and the second cooling chamber 540 of the second buffer module 500. The guide rail 483 is placed so that the longitudinal direction is in line with the first direction 12. The guide rail 483 guides the development unit robot 482 to linearly move in the first direction 12. The development unit robot 482 has a hand 484, an arm 485, a support 486, and a bracket 487. The hand 484 is fixedly installed in the arm 485. The arm 485 is provided in the stretchable structure to allow the hand 484 to be movable in the horizontal direction. The support 486 is provided to be placed in the third direction 16 which is the longitudinal direction thereof. The arm 485 is coupled to the support 486 to be linearly movable along the support 486 in the third direction 16. The support 486 is fixedly coupled to the bracket 487. The bracket 487 is coupled to the guide rail 483 to be movable along the guide rail 483.

All of the development chambers 460 have the same structure. However, the types of development liquids used in the respective development chambers 460 may be different from each other. The development chamber 460 removes a region to which light is irradiated in the photoresist on the substrate W. In this case, a region to which the light is irradiated in a passivation layer is also removed jointly. Optionally, only a region to which the light is not irradiated the regions of the photoresist and the passivation layer may be removed according to the type of used photoresist.

The development chamber 460 has a container 461, a support plate 462, and a nozzle 463. The container 461 may have a cup shape of which an upper portion is opened. The support plate 462 is positioned in the container 461, and supports the substrate W. The support plate 462 is provided to be rotatable. The nozzle 463 supplies the development liquid onto the substrate W placed on the support plate 462. The nozzle 463 may have a circular tube shape, and supply the development liquid to the center of the substrate W. Optionally, the nozzle 463 may have a length corresponding to a diameter of the substrate W, and the ejection hole of the nozzle 463 may be provided as a slit. Further, a nozzle 464 supplying a cleaning liquid such as deionized water may be further provided to the development chamber 460 in order to clean the surface of the substrate W to which the development liquid is supplied.

The bake chamber 470 heat-treats the substrate W. For example, the bake chambers 470 perform a post bake process of heating the substrate W before the development process is performed, a hard bake process of heating the substrate W after the development process is performed, and a cooling process of cooling the heated substrate W after each bake process. The bake chamber 470 has a cooling plate 471 or a heating plate 472. A cooling means 471 such as cooling water or a thermoelectric element is provided in the cooling plate 473. Further, a heating means 474 such as the heat wire or the thermoelectric element is provided in the heating plate 472. Each of the cooling plate 471 and the heating plate 472 may be provided in one bake chamber 470. Optionally, some of the bake chambers 470 may include only the cooling plate 471, and the other some may include only the heating plate 472.

As described above, in the application and development module 400, the application module 401 and the development module 402 are provided to be separated from each other. Further, when viewed from the top, the application module 401 and the development module 402 may have the same chamber arrangement.

The second buffer module 500 is provided as a passage through which the substrate W is transported between the application and development module 400 and the exposure pre-post treatment module 600. Further, the second buffer module 500 performs a predetermined process such as a cooling process or an edge exposure process with respect to the substrate W. The second buffer module 500 includes a frame 510, a buffer 520, a first cooling chamber 530, a second cooling chamber 540, an edge exposure chamber 550, and a second buffer robot 560. The frame 510 has the rectangular parallelepiped shape. The buffer 520, the first cooling chamber 530, the second cooling chamber 540, the edge exposure chamber 550, and the second buffer robot 560 are positioned in the frame 510. The buffer 520, the first cooling chamber 530, and the edge exposure chamber 550 are arranged at a height corresponding to the application module 401. The second cooling chamber 540 is placed at a height corresponding to the development module 402. The buffer 520, the first cooling chamber 530, and the second cooling chamber 540 are sequentially arranged in line in the third direction 16. When viewed from the top, the buffer 520 is arranged in the first direction 12 jointly with the transfer chamber 430 of the application module 401. The edge exposure chamber 550 is arranged to be spaced apart from the buffer 520 or the first cooling chamber 530 by a predetermined distance in the second direction 14.

The second buffer robot 560 transports the substrate W between the buffer 520, the first cooling chamber 530, and the edge exposure chamber 550. The second buffer robot 560 is positioned between the edge exposure chamber 550 and the buffer 520. The second buffer robot 560 may be provided in a similar structure to the first buffer robot 360. The first cooling chamber 530 and the edge exposure chamber 550 perform a subsequent process for the substrates W for which the process is performed in the application module 401. The first cooling chamber 530 cools the substrate W for which the process is performed in the application module 401. The first cooling chamber 530 has a similar structure to the cooling chamber 350 of the first buffer module 300. The edge exposure chamber 550 exposes the edges of the substrates W for which the process is performed in the first cooling chamber 530. The buffer 520 temporarily keeps the substrate W before the substrates W for which the process is performed in the edge exposure chamber 550 are transported to a pre-treatment module 601 to be described below. The second cooling chamber 540 cools the substrates W before the substrates W for which the process is performed in a post-treatment module 602 to be described below are transported to the development module 402. The second buffer module 500 may further have an added buffer at a height corresponding to the development module 402. In this case, the substrates W for which the process is performed in a post-treatment module 602 may be temporarily kept in the added buffer, and then transported to the development module 402.

The exposure pre and post-treatment module 600 may treat a process of applying a passivation layer protecting a photoresist film applied to the substrate W upon immersion exposure when an exposure apparatus 900 performs an immersion exposure process. Further, the exposure pre and post-treatment module 600 may perform a process of cleaning the substrate after the exposure. Further, when the application process is performed by using a chemical amplification type resist, the exposure pre and post-treatment module 600 may perform a post-exposure bake process. The exposure pre and post-treatment module 600 includes a pre-treatment module 601 and a post-treatment module 602. The pre-treatment module 601 performs a process of treating the substrate W before performing the exposure process and the post-treatment module 602 performs a process of treating the substrate after the exposure process. The pre-treatment module 601 and the post-treatment module 602 are placed to be partitioned from each other by the layer. According to an example, the pre-treatment module 601 is positioned above the post-treatment module 602. The pre-treatment module 601 is provided at the same height as the application module 401. The pre-treatment module 602 is provided at the same height as the development module 402. The pre-treatment module 602 includes a passivation layer application chamber 610, a bake chamber 620, and a transfer chamber 630. The passivation layer application chamber 610, the transfer chamber 630, and the bake chamber 620 may be sequentially arranged in the second direction 14. Therefore, the passivation layer application chamber 610 and the bake chamber 620 are positioned to be spaced apart from each other with the transfer chamber 630 interposed therebetween in the second direction 14. A plurality of passivation layer application chambers 610 are provided, and placed to be layered on each other in the third direction 16. Optionally, the plurality of passivation layer application chambers 610 may be provided in each of the first direction 12 and the third direction 16. A plurality of bake chambers 620 are provided, and placed to be layered on each other in the third direction 16. Optionally, the plurality of bake chambers 620 may be provided in each of the first direction 12 and the third direction 16.

The transfer chamber 630 is positioned in line with the first cooling chamber 530 of the second buffer module 500 in the first direction 12. A pre-treatment robot 632 is positioned in the transfer chamber 630. The transfer chamber 630 has a substantially squarer or rectangular shape. The pre-treatment robot 632 transfers the substrate W between the passivation layer application chamber 610, the bake chambers 620, the buffer 520 of the second buffer module 500, and a first buffer 720 of an interface module 700 to be described below. The pre-treatment robot 632 has a hand 633, an arm 634, and a support 635. The hand 633 is fixedly installed in the arm 634. The arm 634 is provided in a stretchable structure and a rotatable structure. The arm 634 is coupled to the support 635 to be linearly movable along the support 635 in the third direction 16. The passivation layer application chamber 610 applies the passivation layer protecting the resist film upon the immersion exposure onto the substrate W. The passivation layer application chamber 610 has a housing 611, a support plate 612, and a nozzle 613. The housing 611 may have a cup shape of which an upper portion is opened. The support plate 612 is positioned in the housing 611, and supports the substrate W. The support plate 612 is provided to be rotatable. The nozzle 613 supplies a passivation liquid for forming the passivation layer onto the substrate W placed on the support plate 612. The nozzle 613 may have a circular tube shape, and supply the passivation liquid to the center of the substrate W. Optionally, the nozzle 613 may have a length corresponding to a diameter of the substrate W, and the ejection hole of the nozzle 613 may be provided as a slit. In this case, the support plate 612 may be provided in a fixed state. The passivation liquid includes a foamed material. The passivation liquid may adopt a photoresist and a material having low affinity with water. For example, the passivation liquid may contain a fluorine-based solvent. The passivation layer application chamber 610 supplies the passivation liquid to the central region of the substrate W while rotating the substrate W placed on the support plate 612.

The bake chamber 620 heat-treats the substrate W applied with the passivation layer. The bake chamber 620 has a cooling plate 621 or a heating plate 622. A cooling means 621 such as cooling water or a thermoelectric element is provided in the cooling plate 623. Alternatively, a heating means 622 such as the heat wire or the thermoelectric element is provided in the heating plate 624. Each of the heating plate 622 and the cooling plate 621 may be provided in one bake chamber 620. Optionally, some of the bake chambers 620 may include only the heating plate 622, and the other some may include only the cooling plate 621.

The pre-treatment module 602 includes a cleaning chamber 660, a post-exposure bake chamber 670, and a transfer chamber 680. The cleaning chamber 660, the transfer chamber 680, and the post-exposure bake chamber 670 are sequentially arranged in the second direction 14. Therefore, the cleaning chamber 660 and the post-exposure bake chamber 670 are positioned to be spaced apart from each other with the transfer chamber 680 interposed therebetween in the second direction 14. A plurality of cleaning chambers 660 are provided, and placed to be layered on each other in the third direction 16. Optionally, the plurality of cleaning chambers 660 may be provided in each of the first direction 12 and the third direction 16. A plurality of exposure-post bake chambers 670 may be provided, and placed to be layered on each other in the third direction 16. Optionally, the plurality of post-exposure bake chambers 670 may be provided in each of the first direction 12 and the third direction 16.

The transfer chamber 680 is positioned in line with the second cooling chamber 540 of the second buffer module 500 in the first direction 12 when viewed from the top. The transfer chamber 680 has a substantially squarer or rectangular shape. A post-treatment robot 680 is positioned in the transfer chamber 682. The post-treatment robot 682 transports the substrate W between the cleaning chambers 660, the post-exposure bake chambers 670, the second cooling chamber 540 of the second buffer module 500, and a second buffer 730 of the interface module 700 to be described below. The post-treatment robot 682 provided in the post-treatment module 602 may be provided in the same structure as the pre-treatment robot 632 provided in the pre-treatment module 601.

The cleaning chamber 660 cleans the substrate W after the exposure process. The cleaning chamber 660 has a housing 661, a support plate 662, and a nozzle 663. The housing 661 may have a cup shape of which an upper portion is opened. The support plate 662 is positioned in the housing 661, and supports the substrate W. The support plate 662 is provided to be rotatable. The nozzle 663 supplies a cleaning liquid onto the substrate W placed on the support plate 662. As the cleaning liquid, water such as deionized water may be used. The cleaning chamber 660 supplies the cleaning liquid to the central region of the substrate W while rotating the substrate W placed on the support plate 662. Optionally, the nozzle 663 may linearly move or rotatably move up to an edge region from the central region of the substrate W while the substrate W rotates. The post-exposure bake chamber 670 heats the substrate for which the exposure process is performed by using far-ultraviolet rays. The post-exposure bake process amplifies acid generated in the photoresist by the exposure by heating the substrate W to complete a property change of the photoresist. The post-exposure bake chamber 670 has the heating plate 672. A heating means 674 such as the heat wire or the thermoelectric element is provided in the heating plate 672. The post-exposure bake chamber 670 may further include the cooling plate 671 therein. A cooling means 671 such as cooling water or a thermoelectric element is provided in the cooling plate 673. Further, optionally, a bake chamber having only the cooling plate 671 may be further provided.

As described above, in the exposure pre and post-treatment module 600, the pre-treatment module 601 and the post-treatment module 602 are provided to be completely separated from each other. Further, the transfer chamber 630 of the pre-treatment module 601 and the transfer chamber 680 of the post-treatment module 602 are provided in the same size to be provided to completely overlap with each other when viewed from the top. Further, the passivation layer application chamber 610 and the cleaning chamber 660 are provided in the same size to be provided to completely overlap with each other when viewed from the top. Further, the bake chamber 620 and the post-exposure bake chamber 670 are provided to completely overlap with each other when viewed from the top.

The interface module 700 transfers the substrate W between the exposure pre and post-treatment module 600 and the exposure apparatus 900. The interface module 700 includes a frame 710, a first buffer 720, a second buffer 730, and an interface robot 740. The first buffer 720, the second buffer 730, and the interface robot 740 are positioned in the frame 710. The first buffer 720 and the second buffer 730 are spaced apart from each other by a predetermined distance, and placed to be stacked on each other. The first buffer 702 is placed to be higher than the second buffer 730. The first buffer 720 is positioned at a height corresponding to the pre-treatment module 601, and the second buffer 730 is placed at a height corresponding to the post-treatment module 602. When viewed from the top, the first buffer 720 is placed in line with the transfer chamber 630 of the pre-treatment module 601 in the first direction 12, and the second buffer 730 is positioned to be placed in line with the transfer chamber 630 of the post-treatment module 602 in the first direction.

The interface robot 740 is positioned to be spaced apart from the first buffer 720 and the second buffer 730 in the second direction 14. The interface robot 740 transports the substrate W between the first buffer 720, the second buffer 730, and the exposure apparatus 900. The interface robot 740 has a substantially similar structure to the second buffer robot 560.

Before the substrates W for which the process is performed in the pre-treatment module 601 are moved to the exposure apparatus 900, the first buffer 720 temporarily keeps the substrates W. In addition, before the substrates W for which the process is performed in the exposure apparatus 900 are moved to the pre-treatment module 602, the second buffer 730 temporarily keeps the substrates W. The second buffer 720 includes a housing 721 and a plurality of supports 722. The supports 722 are placed in the housing 721, and provided to be spaced apart from each other in the third direction 16. One substrate W is placed on each support 722. The housing 721 has an opening (not illustrated) in the direction in which the interface robot 740 is provided and the direction in which the pre-treatment robot 632 is provided so that the interface robot 740 and the pre-treatment robot 632 may load or unload the substrate W on or from the support 722. The second buffer 730 has a substantially similar structure to the first buffer 720. However, the housing 4531 of the second buffer 730 has an opening (not illustrated) in a direction in which the interface robot 740 is provided and a direction in which the pre-treatment robot 682 is provided. Only the buffers and the robot may be provided in the interface module as described above without providing a chamber that performs a predetermined process for the substrate W.

Next, an example of performing the process by using the substrate treating facility 1 will be described.

The cassette 20 storing the substrates W is placed on the mounting table of the load port 100. The door of the cassette 20 is opened by a door opener. The index robot 220 takes out the substrate W from the cassette 20, and transports the substrate W to the second buffer 330.

The first buffer robot 360 transports the substrate W kept in the second buffer 30 to the first buffer 320. The application unit robot 432 takes out the substrate W from the first buffer 320, and transports the substrate W to the bake chamber 420 of the application module 401. The bake chamber 420 sequentially performs pre bake and cooling processes. The application unit robot 432 takes out the substrate W from the bake chamber 420, and transports the substrate W to the resist application chamber 410. The resist application chamber 410 applies the photoresist onto the substrate W. Thereafter, when the photoresist is applied onto the substrate W, the application unit robot 432 takes out the substrate W from the resist application chamber 410, and transports the substrate W to the bake chamber 420 from the resist application chamber 410. The bake chamber 420 performs a soft bake process for the substrate W.

The application unit robot 432 takes out the substrate W from the bake chamber 420, and transports the substrate W to the first cooling chamber 530 of the second buffer module 500. The cooling process is performed for the substrate W in the first cooling chamber 530. The substrate W for which the process is performed in the first cooling chamber 530 is transported to the edge exposure chamber 550 by the second buffer robot 560. The edge exposure chamber 550 performs a process of exposing the edge region of the substrate W. The substrate W for which the process is completed in the edge exposure chamber 550 is transported to the buffer 520 by the second buffer robot 560.

The pre-treatment robot 632 takes out the substrate W from the buffer 520, and transports the substrate W to the passivation layer application chamber 610 of the pre-treatment module 601. The passivation layer application chamber 610 applies the passivation layer onto the substrate W. Thereafter, the pre-treatment robot 632 transports the substrate W from the passivation layer application chamber 610 to the bake chamber 620. The bake chamber 620 performs heat-treatment such as heating and cooling for the substrate W.

The pre-treatment robot 632 takes out the substrate W from the bake chamber 620, and transports the substrate W to the first buffer 720 of the interface module 700. The interface robot 740 transports the substrate W from the first buffer 720 to the exposure apparatus 900. The exposure apparatus 900 performs the exposure, e.g., the immersion exposure process for a treated surface of the substrate W. When the exposure process is completed for the substrate W in the exposure apparatus 900, the interface robot 740 transports the substrate W from the exposure apparatus 900 to the second buffer 730.

The post-treatment robot 682 takes out the substrate W from the second buffer 730, and transports the substrate W to the cleaning chamber 660 of the post-treatment module 602. The cleaning chamber 660 performs the cleaning process by supplying the cleaning liquid to the surface of the substrate W. When cleaning the substrate W using the cleaning liquid is completed, the post-treatment robot 682 immediately takes out the substrate W from the cleaning chamber 660 and exposes the substrate W, and then transports the substrate to the bake chamber 670. The cleaning liquid attached onto the substrate W is removed by heating the substrate W in the heating plate 672 of the post-exposure bake chamber 570, and simultaneously with this, the acid generated in the photoresist is amplified to complete the property change of the photoresist. The post-treatment robot 682 takes out the substrate W from the post-exposure bake chamber 670, and transports the substrate W to the second cooling chamber 540 of the second buffer module 500.

The second cooling chamber 540 performs cooling of the substrate W.

The development unit robot 482 takes out the substrate W from the second cooling chamber 540, and transports the substrate W to the bake chamber 470 of the development module 402. The bake chamber 470 sequentially performs post bake and cooling processes. The development unit robot 482 takes out the substrate W from the bake chamber 470, and transports the substrate W to the development chamber 460. The development chamber 460 performs the development process by supplying the development liquid onto the substrate W. Thereafter, the development unit robot 482 transports the substrate W from the development chamber 460 to the bake chamber 470. The bake chamber 470 performs the hard bake process for the substrate W.

The development unit robot 482 takes out the substrate W from the bake chamber 470, and transports the substrate W to the cooling chamber 350 of the first buffer module 300. The cooling chamber 350 performs the process of cooling the substrate W. The index robot 360 transports the substrate W from the cooling chamber 350 to the cassette 20. Unlike this, the development unit robot 492 may take out the substrate W from the bake chamber 470 and transport the substrate W to the second buffer 330 of the first buffer module 300, and then the substrate W may be transported to the cassette 20 by the index robot 360.

What is claimed is:

1. A treatment liquid supply nozzle supplying a treatment liquid onto a substrate, comprising:
a nozzle body; and
a nozzle tip connected to the nozzle body, and having an internal flow path through which a treatment liquid is ejected,
wherein the nozzle tip has an anti-static surface capable of removing static electricity.

2. The treatment liquid supply nozzle of claim 1, wherein the nozzle tip is provided by a transparent material so as to check a suck-back, and
the anti-static surface is subjected to ion injection treatment.

3. The treatment liquid supply nozzle of claim 2, wherein the transparent material includes perfluoroalkoxy (PFA).

4. The treatment liquid supply nozzle of claim 1, wherein the nozzle tip is provided by a transparent material so as to check a suck-back, and
the anti-static surface is surface-treated by ion beams to have a surface resistance value of 10⁶ to 10^{9 Ω.}

5. The treatment liquid supply nozzle of claim 2, further comprising:
a nozzle nut member fastened to a thread of the nozzle body so that the nozzle tip is fixed to the nozzle body, and contacting the nozzle tip,
wherein the nozzle nut member has a conductive material and a conductive surface surface-treated with the ion beams.

6. The treatment liquid supply nozzle of claim 5, further comprising:
a grounding member having one end contacting the nozzle nut member and the other end grounded through a nozzle arm on which the nozzle body is supported.

7. The treatment liquid supply nozzle of claim 6, wherein the grounding member includes a ground line having a ring type terminal connected to each of the nozzle fastening member and the nozzle arm.

8. The treatment liquid supply nozzle of claim 6, wherein the grounding member includes a conductive tape or a conductive pattern connected from the nozzle body up to the nozzle arm.

9. The treatment liquid supply nozzle of claim 1, wherein the anti-static surface includes an outer peripheral surface of the nozzle tip and a partial region of the internal flow path.

10. A substrate treating apparatus comprising:
a substrate support unit supporting a substrate; and
a liquid supply unit applying a photosensitive liquid onto the substrate supported on the substrate support unit,
wherein the liquid supply unit includes
an application nozzle supplying the photosensitive liquid,
a nozzle arm in which the application nozzle is positioned at one end portion, and
a driving member positioned at the other end portion of the nozzle arm and moving the nozzle arm, and
the application nozzle includes
a nozzle body supported on the nozzle arm, and
a nozzle tip connected to the nozzle body, and an anti-static surface having an internal flow path through which the photosensitive liquid is ejected and capable of removing static electricity.

11. The substrate treating apparatus of claim 10, wherein the nozzle tip is provided by a transparent material so as to check a suck-back, and
the anti-static surface is subjected to ion injection treatment.

12. The substrate treating apparatus of claim 11, wherein the transparent material includes perfluoroalkoxy (PFA), and
the anti-static surface has conductivity in which a surface resistance value is 10⁶ to 10^{9 Ω.}

13. The substrate treating apparatus of claim 11, further comprising:
a nozzle nut member fastened to a thread of the nozzle body so that the nozzle tip is fixed to the nozzle body, and contacting the nozzle tip,
wherein the nozzle nut member has a conductive material and a conductive surface surface-treated with the ion beams.

14. The substrate treating apparatus of claim 13, further comprising:
a grounding member having one end contacting the nozzle nut member and the other end grounded through a nozzle arm on which the nozzle body is supported.

15. The substrate treating apparatus of claim 14, wherein the grounding member includes a ground line having a ring type terminal connected to each of the nozzle fastening member and the nozzle arm.

16. The substrate treating apparatus of claim 14, wherein the grounding member includes a conductive tape or a conductive pattern connected from the nozzle body up to the nozzle arm.

17. The substrate treating apparatus of claim 10, wherein the anti-static surface includes an outer peripheral surface of the nozzle tip and a partial region of the internal flow path, the liquid supply unit further includes a pre-treatment nozzle applying a pre-treatment liquid,
a plurality of application nozzles is provided, and
the application nozzles and the pre-treatment nozzles are supported on the nozzle body to be arranged in one direction when viewed from the top.

18. A substrate treating apparatus comprising:
a substrate support unit supporting a substrate; and
a liquid supply unit applying a photosensitive liquid onto the substrate supported on the substrate support unit,
wherein the liquid supply unit includes
an application nozzle supplying the photosensitive liquid,
a nozzle arm in which the application nozzle is positioned at one end portion, and
a driving member positioned at the other end portion of the nozzle arm and moving the nozzle arm, and
the application nozzle includes
a nozzle body supported on the nozzle arm,
a nozzle tip connected to the nozzle body, and an anti-static surface having an internal flow path through which the photosensitive liquid is ejected and capable of removing static electricity,
a nozzle nut member fastened to a thread of the nozzle body so that the nozzle tip is fixed to the nozzle body, and contacting the nozzle tip, and
a grounding member having one end contacting the nozzle nut member and the other end grounded through the nozzle arm.

19. The substrate treating apparatus of claim 18, wherein the nozzle tip is provided by a transparent material so as to check a suck-back, and
the anti-static surface is surface-treated with ion beams, and has conductivity.

20. The substrate treating apparatus of claim 18, wherein the grounding member includes a ground line having a ring type terminal connected to each of the nozzle fastening member and the nozzle arm or a conductive tape or a conductive pattern connected from the nozzle body up to the nozzle arm.
